(19) United States
(12) Patent Application Publication
(10) Pub. No.: US 2016/0313503 A1
(43) Pub. Date: Oct. 27, 2016

(54) ELECTRODE-PLACED SUBSTRATE

(71) Applicant: Sumitomo Osaka Cement Co., Ltd, Tokyo (JP)

(72) Inventors: Motohiro Takemura, Tokyo (JP); Junichiro Ichikawa, Tokyo (JP); Tetsuya Fujino, Tokyo (JP)

(21) Appl. No.: 14/867,586

(22) Filed: Sep. 28, 2015

(30) Foreign Application Priority Data
Sep. 30, 2014 (JP) 2014-202253

(51) Int. Cl. G02B 6/12; H05K 1/02; G02F 1/01

(52) U.S. Cl. CPC G02B 6/12; G02F 1/011; H05K 1/0296; H05K 1/0213; G02B 2006/12142; H05K 2201/09209

(57) ABSTRACT

An optical modulation device includes a substrate having a principal surface, and electrodes provided on the principal surface of the substrate. The electrodes have end portion regions on the outer edge side of the principal surface of the substrate in a plan view, and planar-view corner portions provided between tip end outer edges which define the tip end shapes of the end portion regions in a first direction and side surface outer edges which define the side surface shapes of the end portion regions in the plan view have chamfered shapes.

### BACKGROUND OF THE INVENTION

1. Field of the Invention

The present invention relates to an electrode-placed substrate.

2. Description of Related Art

In Japanese Laid-open Patent Publication Nos. 2012-141632, 2002-196295, and 2006-119661, an optical waveguide device used in an optical modulator or the like is described. In the optical waveguide device described in the documents, an electrode-placed substrate is used. Specifically, the optical waveguide device described in the documents includes a substrate, in which an optical waveguide is formed, and a modulation electrode constituted by a signal electrode and a ground electrode, which are provided on the substrate to apply an electric field to the optical waveguide.

In the optical waveguide device described in the documents, the electrodes (the signal electrode and the ground electrode) formed on the substrate are electrically connected to a conductive portion provided in an external member, for example, an electrode provided in a relay substrate positioned in the vicinity of the optical waveguide device, through wire bonding or the like. Accordingly, it becomes possible to apply an electrical signal (for example, a modulation signal for optical modulation) to the electrodes formed on the substrate or to electrically connect the electrodes to a ground potential.

In order to facilitate electrical connection to the conductive portion of the external member, the electrode formed on the substrate has an end portion region which extends toward the outer edge of the substrate and comes into contact with or is close to the outer edge. The electrode on the substrate is electrically connected to the conductive portion of the external member through wire bonding in the end portion region.

In a case where the electrode-placed substrate is used in a device which uses an electrical signal having a high frequency as in an optical modulator, the thickness of the electrode needs to be great (for example, 20 μm or more) from the viewpoint of achieving broadband by reducing the loss of the electrical signal in the electrode. In addition, particularly from a viewpoint of achieving a high frequency in the modulation electrode, a thick coplanar type (CPW type) electrode structure is effectively used, and particularly good characteristics can be obtained by causing the thickness of the electrode to be 30 μm to 100 μm.

In addition, in a case of a thick electrode structure, during electrode pattern inspection, characteristics inspection, a process of dicing into chips, cleaning after dicing, and subsequent processes, crushed matter from the substrate of the optical modulator or the constituent materials of the optical modulator and foreign matter such as dust that is present in a processing chamber or in circulating water of a dicer are likely to be collected in the side surface region of the electrode. In addition, depending on the size of the foreign matter such as dust, the foreign matter is likely to be interposed between the signal electrode and the ground electrode of the coplanar electrode. During the process of dicing into chips, a cutting process is performed by the dicer, and thus the crushed matter from the substrate of the optical modulator or the constituent materials of the optical modulator is likely to act as the foreign matter mentioned above.

As a method of removing the foreign matter mentioned above, ultrasonic cleaning, jet cleaning, DIP cleaning, and the like, which are generally used in a semiconductor fabrication process, may be used. However, there is concern that the electrode may be collapsed and peeled off. Therefore, as the method of removing the foreign matter mentioned above, scrub cleaning using a brush is particularly effective.

Scrub cleaning used in an electronic device manufacturing process is classified by the use of a brush and a sponge brush. Here, scrub cleaning indicates cleaning using a brush. As the bristle material of the brush, nylon or PVA is generally used. In order to dislodge foreign matter such as crushed matter between electrodes, the bristle material of the brush needs to intrude between the electrodes and needs to have appropriate elasticity. Therefore, a brush using a bristle material tapered to have a diameter of 20 micrometers or less at the tip end portion, or a brush using a bundle of short fine wires having a diameter of 20 micrometers or less and a length of several millimeters, is used.

In addition, in order to form a thick electrode structure, an electrocasting (photo electroplating) process is generally used. In a case of an electrode having a thickness of 40 μm or more, a photoresist which acts as a mold requires comprehensive characteristics such as resolution, resolution aspect ratio (L/S), adhesion to a substrate, and the like. In addition, as the electrode material, gold (Au), silver (Ag), copper (Cu), or the like is appropriate, and the photoresist also requires resistance to such plating solutions. As a commercially available photoresist, a photoresist for MEMS, such as SU8, KMPR, or TMMR-S2000 is appropriate. Most of these photoresists are of a negative type. The photoresist is removed after plating of a predetermined thickness is finished. However, in general, it is difficult to remove and unstick a negative type photoresist by a simple immersion method although the negative type photoresist has excellent chemical resistance and adhesion compared to a positive type resist. The type of removal is primarily swelling and peeling other than dissolution and dilution using a peeling agent, and thus a showering type of cleaning method performed using a dedicated peeling agent (Remover PG, Remover N01, or Remover K made by KMPR) is employed. In a case of a form such as a broadband electrode provided on LiNbO₃, a cleaning process through showering requires a large amount of time (about one hour in a case of a thickness of 50 μm). Furthermore, in a bent portion of the electrode, asymmetric stress is applied to a signal strip line due to the swelling of the photoresist as the mold, and thus the signal strip line is deformed or peeled off.

In order to avoid this problem, it is extremely effective to remove the swollen photoresist by scrub cleaning. A portion of the photoresist which is softened to the degree of the bristle material of the brush and is swollen is scraped off by the brush. In a case of shower cleaning, the swollen photoresist is not washed off, until the swollen portion is penetrated deep by the ejection pressure and the viscosity of the swollen portion becomes a predetermined level or lower. In a case of brush cleaning, when the swollen photoresist is softened to the degree of the bristle material of the brush, the swollen photoresist is scraped off, which results in a significant reduction in time.

The progress of the swollen portion is basically based on the diffusion rule, and thus the depth of the swollen portion (the distance of the swollen portion from the interface with the peeling agent) is increased as an immersion time is increased, and stress applied to the electrode is also increased. As described above, in order to prevent the deformation or peeling of the bent portion of the signal strip line caused by the swelling of the photoresist as the mold, reducing the immersion time, that is, cleaning time and immediately scraping off the swollen portion of the photoresist as the mold are extremely effective. An appropriate form for the brush is the same as in a case of removing foreign matter such as crushed matter infiltrating between electrodes. Here, the brush needs to be made of a material that is not dissolvable by the peeling agent that is used.

However, although the electrode is provided on a principal surface of the substrate or on a buffer layer formed on the principal surface of the substrate, the substrate or the buffer layer is made of a different material from that of the electrode. Therefore, in a case where temperature conditions used in an electrode forming process of forming the electrode on the substrate through plating or the like are different from temperature conditions used in other subsequent processes or during use, stress caused by the difference in the coefficient of thermal expansion between materials occurs at the interface between the electrode and an element provided therebelow under the latter temperature conditions. Such stress becomes the cause of a reduction in the bonding force of the electrode and the substrate.

In addition, not only are the temperature conditions used in the electrode forming process are generally different from the temperature conditions used in the other subsequent processes and during use, but also the thickness of the electrode needs to be great as described above. Therefore, high stress remains in the interface between the electrode and the element provided therebelow. In addition, since the end portion region of electrode extends toward the outer edge of the substrate, a tip end portion thereof in the vicinity of the outer edge has, for example, a corner portion of a right angle in a plan view. At the interface between the corner portion and the element provided therebelow, particularly high stress is likely to remain. Therefore, the corner portion of the end portion region of the electrode is particularly easily peeled off from the substrate.

In addition, as described above, since the thickness of the electrode needs to be great from the viewpoint of achieving broadband and the end portion region is positioned at the outer edge of the substrate or in the vicinity of the outer edge, physical stimulation (for example, contact by handling means during handling of the electrode-provided substrate, or contact by a brush during scrub cleaning) is likely to be applied to the end portion region. As a result, the end portion region of the electrode is likely to be peeled off from the substrate by such physical stimulation.

Furthermore, there may be cases where the bristles of the brush are damaged by the peeled end portion of the electrode during scrub cleaning, and a portion of the bristles of the brush is scraped off and then becomes foreign matter. In addition, as described above, there may be cases where the crushed matter from the substrate of the modulator or the constituent materials of the modulator becomes foreign matter. The foreign matter generated as described above is likely to be collected in the side surface region of the electrode, and depending on the size of the foreign matter, the foreign matter is likely to be interposed between the signal electrode and the ground electrode. However, it is difficult to completely remove the foreign matter by scrub cleaning due to the thickness of the electrode, and there may be cases where the foreign matter remains. There may be cases where the foreign matter that is not interposed between the electrodes is removed by ultrasonic cleaning or shower cleaning. However, it is difficult to remove foreign matter such as dust interposed between the signal electrode and the ground electrode using the above-mentioned method. Regarding an electrode having a single line pattern such as a microstrip electrode, it is relatively easy to remove the photoresist for MEMS through scrub cleaning. However, regarding an electrode having a pattern such as a coplanar electrode or a coplanar strip electrode in which a signal electrode and a ground electrode are adjacent to each other, it is difficult to remove the photoresist for MEMS through scrub cleaning.

For the above-described reasons, in the electrode-placed substrate according to the related art, there is a problem in that the end portion region of the electrode is easily peeled off from the substrate, and there is a problem in that foreign matter as the fibers of the brush and crushed matter of the substrate is likely to remain in the side surface region of the electrode even after scrub cleaning is performed.

The present invention has been made taking the foregoing problems into consideration, and an object thereof is to provide an electrode-placed substrate capable of preventing an end portion region of an electrode from being peeled off from a substrate, and preventing foreign matter from remaining in a side surface region of the electrode after scrub cleaning.

### SUMMARY OF THE INVENTION

In order to solve the problems, an electrode-placed substrate according to the present invention includes: a substrate having a principal surface; and a coplanar electrode or a coplanar strip electrode which has a pair of a signal electrode and a ground electrode provided on the principal surface of the substrate, in which the electrode has an end portion region on an outer edge side of the principal surface of the substrate in a plan view, the end portion region extending in a first direction intersecting the outer edge, and in the plan view, a planar-view corner portion provided between a tip end outer edge which defines a tip end shape of the end portion region in the first direction and a side surface outer edge which defines a side surface shape of the end portion region has a chamfered shape, or in a sectional view across a section which is parallel to the first direction and is perpendicular to the principal surface of the substrate, a sectional-view corner portion provided between the tip end outer edge which defines the tip end shape of the end portion region in the first direction and an upper surface outer edge which defines an upper surface shape of the end portion region has a chamfered shape.

In the electrode-placed substrate according to the present invention, in a case where the planar-view corner portion has the chamfered shape, the planar-view corner portion has a curved shape without an angle and/or the planar-view corner portion has a shape with a greater angle than in a case where the planar-view corner portion does not have a chamfered shape. Accordingly, stress is less likely to remain in the planar-view corner portion, and thus the planar-view corner portion is prevented from peeling off from the substrate. In addition, in a case where the sectional-view corner portion has the chamfered shape, the sectional-view corner portion has a shape in which a region, to which physical stimulation (for example, contact by handling means during handling of the electrode-placed substrate or contact by a brush during scrub cleaning) is likely to be applied, is cut off. Accordingly, the peeling of the end portion region of the electrode from the substrate due to physical stimulation is prevented. For the above reasons, in the electrode-placed substrate according to the present invention, the peeling of the end portion region of the electrode from the substrate is prevented.

In addition, since the peeling of the end portion region of the electrode from the substrate is prevented, the bristles of the brush used for scrub cleaning are prevented from being damaged and cut by the peeled end portion of the electrode, and thus the generation of foreign matter caused by the bristles of the brush is suppressed. Moreover, since the planar-view corner portion has the chamfered shape, compared to a case where the planar-view corner portion does not have the chamfered shape, a portion from which foreign matter is swept out during scrub cleaning is enlarged. Therefore, foreign matter in the side surface regions of the electrode is easily swept by scrub cleaning, and thus foreign matter is prevented from remaining in the side surface region of the electrode after scrub cleaning.

Moreover, in the electrode-placed substrate according to the present invention, it is preferable that a thickness of the end portion region of the signal electrode or the ground electrode is 30 μm or more. In an electrode-placed substrate according to the related art, in a case where the thickness of an end portion region of an electrode is 10 μm or more, the end portion region is particularly easily peeled off from the substrate. Therefore, by causing the thicknesses of the end portion region of the electrode in the present invention to be 30 μm or more, an effect of preventing the end portion region of the electrode from peeling off from the substrate in the present invention is relatively effectively exhibited. Moreover, it becomes easy to bond a conductive member to the end portion region of the electrode. In addition, in the electrode-placed substrate according to the present invention, the thickness of the end portion region of the signal electrode or the ground electrode may be 100 μm or less.

Furthermore, in the electrode-placed substrate according to the present invention, it is preferable that the planar-view corner portion of the end portion region of the signal electrode or the ground electrode has an R-chamfered shape in the plan view. Accordingly, since the planar-view corner portion has a curved shape without an angle, stress is further less likely to remain in the planar-view corner portion. As a result, the peeling of the planar-view corner portion from the substrate is more effectively prevented.

Furthermore, in the electrode-placed substrate according to the present invention, it is preferable that the R-chamfered shape of the planar-view corner portion of the end portion region of the signal electrode or the ground electrode has a radius of curvature of 1 μm or more. Accordingly, stress is particularly less likely to remain in the planar-view corner portion, and thus the peeling of the planar-view corner portion from the substrate is particularly effectively prevented.

Furthermore, in the electrode-placed substrate according to the present invention, it is preferable that the planar-view corner portion of the end portion region of the signal electrode or the ground electrode has a C-chamfered shape in the plan view. Accordingly, the entirety of the planar-view corner portion has a shape with a greater angle than in a case where the planar-view corner portion does not have a chamfered shape. Accordingly, stress is less likely to remain in the planar-view corner portion, and thus the peeling of the planar-view corner portion from the substrate is prevented.

Furthermore, in the electrode-placed substrate according to the present invention, it is preferable that the C-chamfered shape of the planar-view corner portion of the end portion region of the signal electrode or the ground electrode has a chamfer length of 0.5 μm or more. Accordingly, stress is particularly less likely to remain in the planar-view corner portion, and thus the peeling of the planar-view corner portion from the substrate is particularly effectively prevented.

According to the present invention, an electrode-placed substrate capable of preventing an end portion region of an electrode from being peeled off from a substrate is provided.

### BRIEF DESCRIPTION OF THE DRAWINGS

FIG. 1 is a schematic view of the planar configuration of an optical modulator which uses an electrode-placed substrate.

FIG. 2 is a sectional view of an optical modulation device taken along line II-II illustrated in FIG. 1.

FIG. 3 is a view illustrating the planar configuration of the vicinity of a relay section of the optical modulation device.

FIGS. 4A to 4C are sectional views of the optical modulation device taken along predetermined lines of FIG. 3.

FIGS. 5A to 5C are views illustrating a method of manufacturing the optical modulator.

FIG. 6 is a view illustrating the planar configuration of the vicinity of a relay section of an optical modulation device according to a modification example.

FIGS. 7A to 7C are sectional views of the optical modulation device taken along predetermined lines of FIG. 6.

FIGS. 8A, 8B, 8C, 8D, and 8E are tables showing the experimental results of Examples 1 to 35.

### DETAILED DESCRIPTION OF THE INVENTION

Hereinafter, an electrode-placed substrate according to embodiments will be described in detail with reference to the accompanying drawings. In each of the drawings, like elements are denoted by like reference numerals if possible. The dimensional ratios of the constituent elements or between the constituent elements in the drawings are arbitrary for ease of understanding of the drawings.

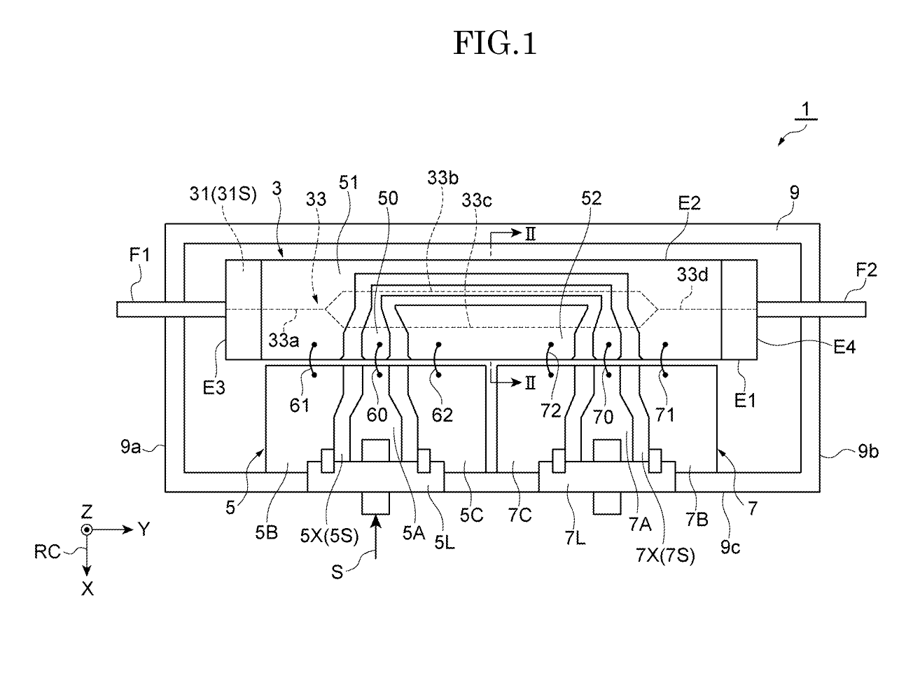

FIG. 1 is a schematic view of the planar configuration of an optical modulator which uses an electrode-placed attached substrate of an embodiment. As illustrated in FIG. 1, an optical modulator 1 of this embodiment is a device which modulates continuous light introduced through an optical fiber F1 and outputs the modulation light to an optical fiber F2. The optical modulator 1 may include an optical modulation device 3 which is the electrode-placed substrate of this embodiment, a relay section 5, a terminal end section 7, and a package case 9.

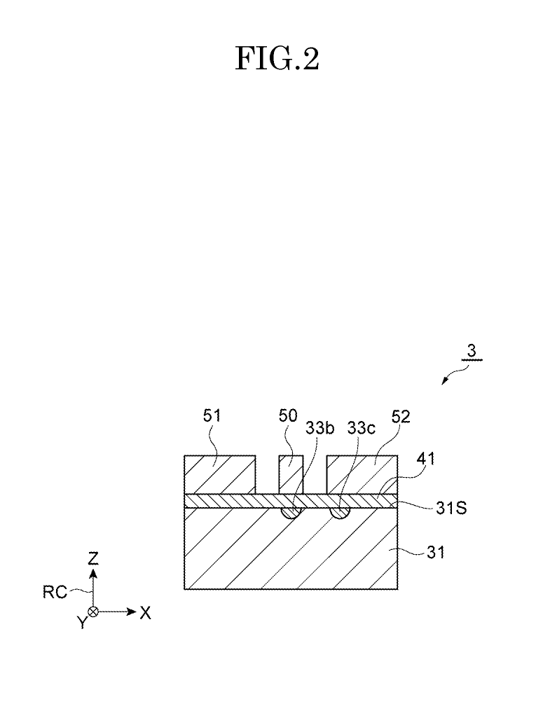

In FIG. 1, a orthogonal coordinate system RC is shown, and in each of the drawings of FIG. 2 and below, the orthogonal coordinate system RC corresponding to FIG. 1 is shown if necessary.

The package case 9 is a box-shaped member that extends in a Y-axis direction, and is made of metal such as stainless steel. The package case 9 includes one end surface 9a and the other end surface 9b which are both end surfaces in the Y-axis direction. One end surface 9a is provided with an opening through which the optical fiber F1 is inserted, and the other end surface 9b is provided with an opening through which the optical fiber F2 is inserted. The package case 9 accommodates, for example, the optical modulation device 3, the relay section 5, and the terminal end section 7. The continuous light introduced through the optical fiber F1 from the outside is supplied to the optical modulation device 3.

The relay section 5 relays an electrical signal S as a modulation signal supplied from the outside, and outputs the electrical signals to the optical modulation device 3. The relay section 5 receives the electrical signal via an electrical signal input connector 5L provided, for example, in a side surface 9c of the package case 9 in an X-axis direction and inputs the electrical signal to the optical modulation device 3. The relay section 5 includes a substrate 5X having a substantially flat principal surface 5S that extends along an XY-plane, a signal electrode 5A provided on the principal surface 5S, a first ground electrode 5B, and a second ground electrode 5C. The signal electrode 5A, the first ground electrode 5B, and the second ground electrode 5C are separated from each other on the principal surface 5S of the substrate 5X. The signal electrode 5A, the first ground electrode 5B, and the second ground electrode 5C are electrodes having shapes that extend along the XY-plane, and are made of a material that is a good conductor at a high frequency, for example, metal such as gold (Au), silver (Ag), or copper (Cu), or a superconducting material. The signal electrode 5A guides the electrical signal S introduced from the outside via the electrical signal input connector 5L to the optical modulation device 3. The first ground electrode 5B and the second ground electrode 5C are electrically connected to a ground potential, and for example, they are electrically connected to the package case 9 having the ground potential via a shielding portion of the connector 5L.

The optical modulation device 3 of the electrode-placed substrate of this embodiment is a device which modulates a carrier-light as continuous light, pulsed light, or the like input from the optical fiber F1 into modulation light according to the electrical signal S output from the relay section 5, and is, for example, an LN optical modulation device. The optical modulation device 3 includes a substrate 31, an optical waveguide 33, a signal electrode 50, a first ground electrode 51, and a second ground electrode 52. A pair of the signal electrode 50 and the first ground electrode 51 constitutes a coplanar electrode or a coplanar strip electrode. Additionally, a pair of the signal electrode 50 and the second ground electrode 52 constitutes a coplanar electrode or a coplanar strip electrode.

The substrate 31 is made of a dielectric material which exhibits an electro-optic effect, for example, lithium niobate (LiNbO₃) (hereinafter, referred to as LN). The substrate 31 extends along the Y-axis direction. The substrate 31 has a substantially flat principal surface 31S that extends along the XY-plane. The principal surface 31S in this embodiment has a rectangular shape, and has four outer edges in a plan view (when viewed in a direction perpendicular to the principal surface 31S (Z-axis direction)), that is, an outer edge E1, an outer edge E2, an outer edge E3, and an outer edge E4. The outer edge E1 and the outer edge E2 extend along the Y-axis direction, and the outer edge E3 and the outer edge E4 extend along the X-axis direction. The outer edge E1 opposes the relay section 5 and the terminal end section 7 while being separated therefrom in the plan view. The shape of the principal surface 31S may also be a shape other than the rectangular shape, for example, a polygonal shape such as a parallelogram shape.

The optical waveguide 33 is provided in the substrate 31, and in this embodiment, is provided in the vicinity of the principal surface 31S of the substrate 31. The optical waveguide 33 is made of a dielectric material with an electro-optic effect, for example, LN in which metal such as titanium (Ti) is thermally diffused. The refractive index of the material forming the optical waveguide 33 is higher than that of the material forming the substrate 31.

In this embodiment, the optical waveguide 33 is a Mach-Zehnder (MZ) type optical waveguide. Specifically, the optical waveguide 33 includes an input waveguide 33a which is a Y-branch optical waveguide, a first arm waveguide 33b, a second arm waveguide 33c, and an output waveguide 33d which is a Y-junction optical waveguide.

The input waveguide 33a extends from one end portion of the substrate 31 in the Y-axis direction along the Y-axis direction and branches off to be connected to the input ends of the first arm waveguide 33b and the second arm waveguide 33c. The first arm waveguide 33b and the second arm waveguide 33c extend along the Y-axis direction, and the output ends thereof are respectively connected to the input ends of the output waveguide 33d. The output waveguide 33d extends from its input ends along the Y-axis direction and is joined to extend to the other end portion of the substrate 31 in the Y-axis direction along the Y-axis direction.

The signal electrode 50, the first ground electrode 51, and the second ground electrode 52 are provided to be separated from each other on the principal surface 31S of the substrate 31. The signal electrode 50, the first ground electrode 51, and the second ground electrode 52 are electrodes having shapes that extend along the XY-plane, and are made of a material that is a good conductor at a high frequency, for example, metal such as gold (Au), silver (Ag), or copper (Cu), or a superconducting material. The signal electrode 50, the first ground electrode 51, and the second ground electrode 52 are electrodes for applying an electric field according to the electrical signal S of the optical modulator 1 to the first arm waveguide 33b and the second arm waveguide 33c. Therefore, the signal electrode 50 has a portion that extends along the first arm waveguide 33b so as to apply the electric field to the first arm waveguide 33b, and the second ground electrode 52 has a portion that extends along the second arm waveguide 33c so as to apply the electric field to the second arm waveguide 33c. The signal electrode 50 guides the electrical signal S output from the signal electrode 5A of the relay section 5 from one end portion of the signal electrode 50 to the other end portion of the signal electrode 50 through the aforementioned portion that extends along the first arm waveguide 33b.

One end portion of the signal electrode 50 is electrically connected to the signal electrode 5A of the relay section 5 by a conductive member 60 such as a bonding wire. Accordingly, the electrical signal S is input from the relay section 5 to one end portion of the signal electrode 50. The first ground electrode 51 is electrically connected to the first ground electrode 5B of the relay section 5 by a conductive member 61 such as a bonding wire. The second ground electrode 52 is electrically connected to the second ground electrode 5C of the relay section 5 by a conductive member 62 such as a bonding wire. Accordingly, the first and second ground electrodes 51 and 52 are electrically connected to the ground potential, respectively. The detailed configurations of the signal electrode 50, the first ground electrode 51, and the second ground electrode 52 will be described later.

FIG. 2 is a sectional view of the optical modulation device 3 taken along line II-II illustrated in FIG. 1. As illustrated in FIG. 2, in this embodiment, the first arm waveguide 33b and the second arm waveguide 33c are provided in the vicinity of the principal surface 31S of the substrate 31. In addition, a buffer layer 41 is provided on the principal surface 31S of the substrate 31. The buffer layer 41 is made of a material having a lower refractive index than those of the first and second arm waveguides 33b and 33c, and for example, is made of a dielectric material such as silicon oxide (SiO₂). The buffer layer 41 is interposed between the first and second arm waveguides 33b and 33c, and the signal electrode 50 and the second ground electrode 52, and reduces propagation loss of light guided by the first and second arm waveguides 33b and 33c, due to the signal electrode 50, the first ground electrode 51, and the second ground electrode 52. The optical modulation device 3 may not include the buffer layer 41.

The terminal end section 7 is a member which absorbs the electrical signal S output from the other end of the signal electrode 50 or output the electrical signal S to the outside of the optical modulator 1. Specifically, the terminal end section 7 includes a substrate 7X having a substantially flat principal surface 7S that extends along the XY-plane, a signal electrode 7A, a first ground electrode 7B, and a second ground electrode 7C which are provide on the principal surface 7S. The signal electrode 7A, the first ground electrode 7B, and the second ground electrode 7C are separated from each other on the principal surface 7S of the substrate 7X. The signal electrode 7A, the first ground electrode 7B, and the second ground electrode 7C are electrodes having shapes that extend along the XY-plane, and are made of a material that is a good conductor at a high frequency, for example, metal such as gold (Au), silver (Ag), or copper (Cu), or a superconducting material.

The signal electrode 7A is electrically connected to the signal electrode 50 of the optical modulation device 3 by a conductive member 70 such as a bonding wire. Accordingly, the electrical signal S is input from the other end portion of the signal electrode 50 to one end portion of the signal electrode 7A. The first ground electrode 7B is electrically connected to the first ground electrode 51 of the optical modulation device 3 by a conductive member 71 such as a bonding wire. The second ground electrode 7C is electrically connected to the second ground electrode 52 of the optical modulation device 3 by a conductive member 72 such as a bonding wire. The electrical signal S input to the signal electrode 7A is output to the outside of the optical modulator 1, for example, via an electrical signal output connector 7L provided in the side surface 9c of the package case 9. The first ground electrode 7B and the second ground electrode 7C are electrically connected to the ground potential, and for example, are electrically connected to the package case 9 having the ground potential via the connector 7L.

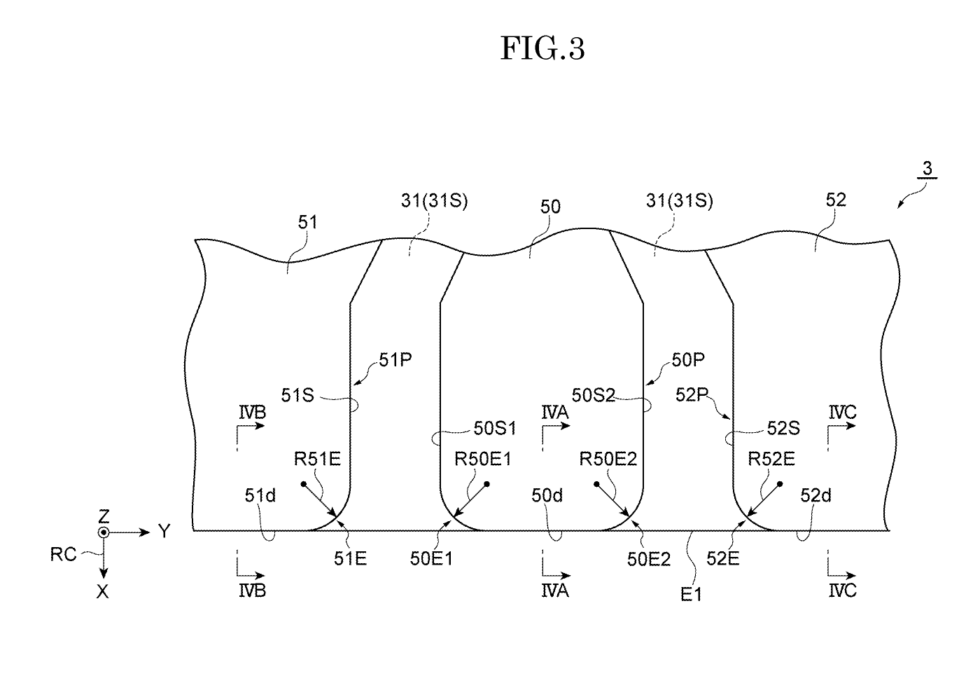

Next, the detailed configurations of the signal electrode 50, the first ground electrode 51, and the second ground electrode 52 are described. FIG. 3 is a view illustrating the planar configuration of the vicinity of the relay section of the optical modulation device. In FIG. 3, illustration of the conductive members 60, 61, and 62 is omitted.

As illustrated in FIG. 3, the signal electrode 50 includes an end portion region 50P which is in a region of the principal surface 31S on the outer edge E1 side. The first ground electrode 51 includes an end portion region 51P which is in a region of the principal surface 31S on the outer edge E1 side. The second ground electrode 52 includes an end portion region 52P which is in a region of the principal surface 31S on the outer edge E1 side. The end portion region 50P, the end portion region 51P, and the end portion region 52P are regions for electrical connection to conductive portions of members provided outside the optical modulation device 3, and in this embodiment, are regions for electrical connection to the signal electrode 5A, the first ground electrode 5B, and the second ground electrode 5C of the relay section 5, respectively.

Each of the end portion regions 50P, 51P, and 52P extends along the +X-axis direction (first direction) which is a direction perpendicularly intersecting the outer edge E1 in the plan view, and may also extends in a direction intersecting the outer edge E1 in the plan view at an acute angle or an obtuse angle. In addition, each of the end portion regions 50P, 51P, and 52P extends to the outer edge E1 of the principal surface 31S (that is, the tip ends of the end portion regions 50P, 51P, and 52P on the outer edge E1 side overlap the outer edge E1 in the plan view), and the tip ends of the end portion regions 50P, 51P, and 52P may also be separated from the outer edge E1 in the plan view in the −X-axis direction. In this case, the separation distance is, for example, 10 μm or more and 200 μm or less.

In addition, in the plan view, the end portion region 50P includes a tip end outer edge 50d which defines the tip end shape of the end portion region 50P in the first direction, and side surface outer edges 50S1 and 50S2 which define the side surface shapes of the end portion region 50P. In this embodiment, in the plan view, the tip end outer edge 50d extends along the Y-axis direction, and the side surface outer edges 50S1 and 50S2 extend along the X-axis direction. The signal electrode 50 includes a planar-view corner portion 50E1 between the tip end outer edge 50d and the side surface outer edge 50S1 and a planar-view corner portion 50E2 between the tip end outer edge 50d and the side surface outer edge 5052. In addition, the planar-view corner portions 50E1 and 50E2 have chamfered shapes, and specifically, in this embodiment, have R-chamfered shapes having predetermined radius of curvature R50E1 and R50E2, respectively.

Similarly, in the plan view, the end portion region 51P includes a tip end outer edge 51d which defines the tip end shape of the end portion region 51P in the first direction, and a side surface outer edge 51S which defines the side surface shape of the end portion region 51P. In this embodiment, in the plan view, the tip end outer edge 51d extends along the Y-axis direction, and the side surface outer edge 51S extends along the X-axis direction. The first ground electrode 51 includes a planar-view corner portion 51E between the tip end outer edge 51d and the side surface outer edge 51S. In addition, the planar-view corner portion 51E has a chamfered shape, and specifically, in this embodiment, has an R-chamfered shape having a predetermined radius of curvature of R51E.

Similarly, in the plan view, the end portion region 52P includes a tip end outer edge 52d which defines the tip end shape of the end portion region 52P in the first direction, and a side surface outer edge 52S which defines the side surface shape of the end portion region 52P. In this embodiment, in the plan view, the tip end outer edge 52d extends along the Y-axis direction, and the side surface outer edge 52S extends along the X-axis direction. The second ground electrode 52 includes a planar-view corner portion 52E between the tip end outer edge 52d and the side surface outer edge 52S. In addition, the planar-view corner portion 52E has a chamfered shape, and specifically, in this embodiment, has an R-chamfered shape having a predetermined radius of curvature of R52E.

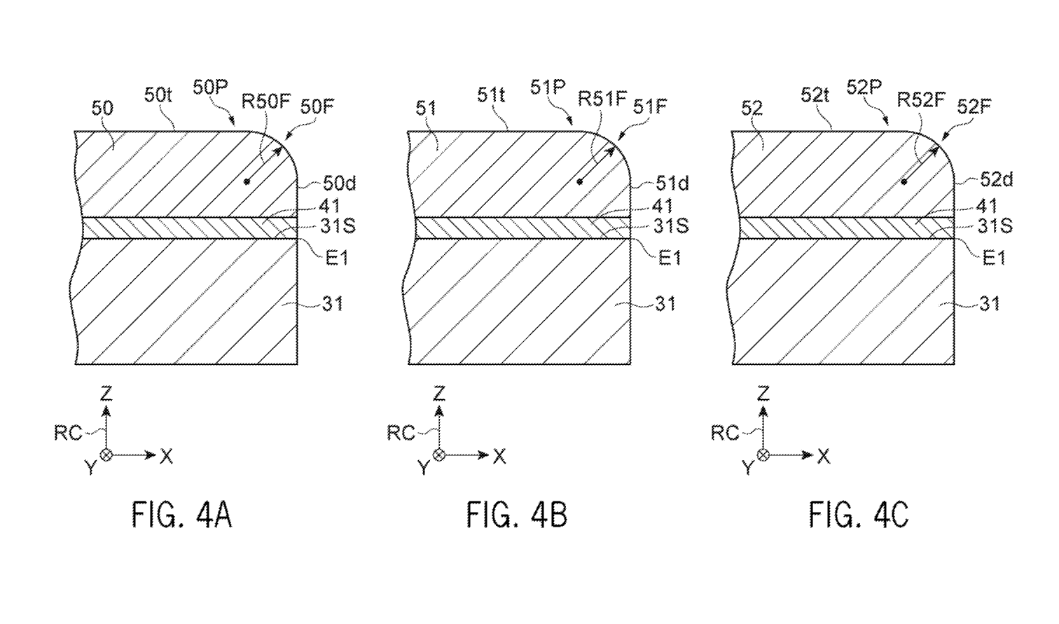

Next, the sectional shape of the optical modulation device 3 will be described. FIG. 4A is a sectional view of the optical modulation device taken along line IVA-IVA of FIG. 3, FIG. 4B is a sectional view of the optical modulation device taken along line IVB-IVB of FIG. 3, and FIG. 4C is a sectional view of the optical modulation device taken along line IVC-IVC of FIG. 3. That is, FIGS. 4A, 4B, and 4C illustrate the sections of the optical modulation device taken along the XZ-plane.

As illustrated in FIG. 4A, in a sectional view, the end portion region 50P includes the tip end outer edge 50d which defines the tip end shape of the end portion region 50P in the first direction, and an upper surface outer edge 50t which defines the upper surface shape of the end portion region 50P. In this embodiment, in the sectional view, the tip end outer edge 50d extends along a Z-axis direction, and the upper surface outer edge 50t extends along the X-axis direction. The signal electrode 50 includes a sectional-view corner portion 50F between the tip end outer edge 50d and the upper surface outer edge 50t. In addition, the sectional-view corner portion 50F has a chamfered shape, and specifically, in this embodiment, has an R-chamfered shape having a predetermined radius of curvature of R50F.

Similarly, as illustrated in FIG. 4B, in the sectional view, the end portion region 51P includes the tip end outer edge 51d which defines the tip end shape of the end portion region 51P in the first direction, and an upper surface outer edge 51t which defines the upper surface shape of the end portion region 51P. In this embodiment, in the sectional view, the tip end outer edge 51d extends along the Z-axis direction, and the upper surface outer edge 51t extends along the X-axis direction. The first ground electrode 51 includes a sectional-view corner portion 51F between the tip end outer edge 51d and the upper surface outer edge 51t. In addition, the sectional-view corner portion 51F has a chamfered shape, and specifically, in this embodiment, has an R-chamfered shape having a predetermined radius of curvature of R51F.

Similarly, as illustrated in FIG. 4C, in the sectional view, the end portion region 52P includes the tip end outer edge 52d which defines the tip end shape of the end portion region 52P in the first direction, and an upper surface outer edge 52t which defines the upper surface shape of the end portion region 52P. In this embodiment, in the sectional view, the tip end outer edge 52d extends along the Z-axis direction, and the upper surface outer edge 52t extends along the X-axis direction. The second ground electrode 52 includes a sectional-view corner portion 52F between the tip end outer edge 52d and the upper surface outer edge 52t. In addition, the sectional-view corner portion 52F has a chamfered shape, and specifically, in this embodiment, has an R-chamfered shape having a predetermined radius of curvature of R52F.

Next, important points of a method of manufacturing the optical modulator 1 of this embodiment will be described. As a method of forming the signal electrode 50, the first ground electrode 51, and the second ground electrode 52 including the planar-view corner portions 50E1, 50E2, 51E, and 52E having the chamfered shapes as illustrated in FIG. 3, on the principal surface 31S of the substrate 31, for example, there is a method of covering the principal surface 31S of the substrate 31 with a mask having a shape corresponding to such a chamfered shape, thereafter forming the signal electrode 50, the first ground electrode 51, and the second ground electrode 52 on the principal surface 31S in such a manner as plating, sputtering, deposition, or the like, and removing the mask. In a case of this method, the signal electrode 50, the first ground electrode 51, and the second ground electrode 52 including the planar-view corner portions 50E1, 50E2, 51E, and 52E having the chamfered shapes can be formed from the start, and thus this method may be called a performed electrode-chamfering method.

As another method, the signal electrode 50, the first ground electrode 51, and the second ground electrode 52 including the planar-view corner portions 50E1, 50E2, 51E, and 52E having the chamfered shapes may be formed by forming a signal electrode, a first ground electrode, and a second ground electrode including planar-view corner portions, which do not have chamfered shapes, on the principal surface 31S of the substrate 31, thereafter covering other regions of the electrodes with a mask to expose regions to be chamfered, and etching the electrodes in such a manner as wet etching or plasma etching. In a case of this method, since the signal electrode, the first ground electrode, and the second ground electrode having typical shapes are formed and thereafter the planar-view corner portion are etched to be chamfered, this method may be called a post-forming electrode-chamfering method.

In addition, as a method of forming the signal electrode 50, the first ground electrode 51, and the second ground electrode 52 including the sectional-view corner portions 50F, 51F, and 52F having the chamfered shapes as illustrated in FIG. 4, on the principal surface 31S of the substrate 31, for example, the signal electrode 50, the first ground electrode 51, and the second ground electrode 52 including the sectional-view corner portions 50F, 51F, and 52F having the chamfered shapes may be formed by forming a signal electrode, a first ground electrode, and a second ground electrode including sectional-view corner portions, which do not have chamfered shapes, on the principal surface 31S of the substrate 31, and thereafter removing portions of the sectional-view corner portions by mechanical or physical means such as cutting or polishing. As another method, the signal electrode 50, the first ground electrode 51, and the second ground electrode 52 including the sectional-view corner portions 50F, 51F, and 52F having the chamfered shapes may be formed by forming a signal electrode, a first ground electrode, and a second ground electrode including sectional-view corner portions, which do not have chamfered shapes, on the principal surface 31S of the substrate 31, thereafter covering other regions of the electrodes to expose regions to be chamfered, and etching the electrodes in such a manner as wet etching or plasma etching.

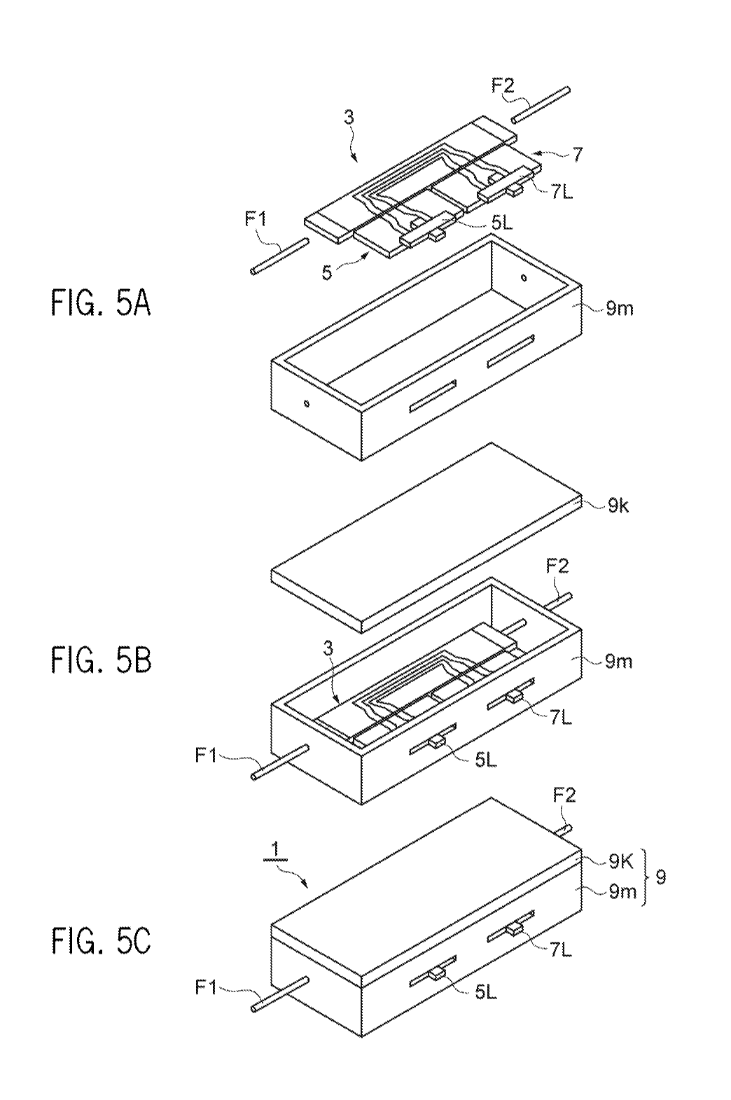

After forming the optical modulation device 3 through the method of forming the signal electrode 50, the first ground electrode 51, and the second ground electrode 52 on the principal surface 31S of the substrate 31 or the like, as illustrated in FIGS. 5A and 5B, the optical modulation device 3, the relay section 5, and the terminal end section 7 are fixed in a body portion 9m of the package case 9 by a conductive adhesive, solder, or the like. In addition, the optical fiber F1 and the optical fiber F2 are respectively inserted through through-holes for the optical fiber F1 and the optical fiber F2, and are optically connected to the optical waveguide of the end surfaces of the optical modulation device 3, and thereafter the through-holes are sealed by solder or the like. Similarly, the connectors 5L and 7L of the relay section 5 and the terminal end section 7 are inserted through through-holes of the package case 9, and thereafter the through-holes are sealed by solder or the like. In addition, electrical connection between the optical modulation device 3, and the relay section 5 and the terminal end section 7 is performed. Subsequently, as illustrated in FIG. 5C, the optical modulation device 3, the relay section 5, and the terminal end section 7 are sealed by fixing a cover portion 9k onto the body portion 9m with a seal or the like. In this manner, the optical modulator 1 having the optical modulation device 3 sealed in the package case 9 can be obtained.

In the optical modulation device 3 according to this embodiment described above, since the planar-view corner portions 50E1, 50E2, 51E, and 52E respectively have the R-chamfered shapes, the planar-view corner portions 50E1, 50E2, 51E, and 52E have curved shapes. That is, in a case where the planar-view corner portions 50E1, 50E2, 51E, and 52E do not have chamfered shapes, it follows that the planar-view corner portion 50E1 has a shape with an angle, specifically, in this embodiment, has a shape with an angle of 90 degrees corresponding to the angle between an extension line of the tip end outer edge 50d and an extension line of the side surface outer edge 50S1, and for the same reason, the planar-view corner portions 50E2, 51E, and 52E also have shapes with an angle of 90 degrees in this embodiment.

However, since each of the planar-view corner portions 50E1, 50E2, 51E, and 52E has the R-chamfered shape, the planar-view corner portions 50E1, 50E2, 51E, and 52E have curved shapes without angles. Accordingly, stress is less likely to remain between the planar-view corner portions 50E1, 50E2, 51E, and 52E and a member positioned immediately therebelow (in this embodiment, the buffer layer 41 (see FIG. 2)), and the planar-view corner portions 50E1, 50E2, 51E, and 52E are prevented from peeling off from the substrate 31. As a result, the end portion regions 50P, 51P, and 52P of the signal electrode 50, the first ground electrode 51, and the second ground electrode 52 are prevented from peeling off from the substrate 31. Therefore, according to the optical modulation device 3 of this embodiment, even when heat stress (for example, heat stress due to heat welding performed when the optical modulation device 3 is sealed in the package case 9) is applied to the optical modulation device 3, the end portion regions 50P, 51P, and 52P of the signal electrode 50, the first ground electrode 51, and the second ground electrode 52 are prevented from peeling off from the substrate 31.

Furthermore, in the optical modulation device 3 according to this embodiment, the thicknesses of the end portion regions 50P, 51P, and 52P of the signal electrode 50, the first ground electrode 51, and the second ground electrode 52 are preferably 30 μm or more. In an electrode-placed substrate such as an optical modulation device according to the related art, in a case where the thickness of an end portion region of an electrode such as a signal electrode is 10 μm or more, the corresponding end portion region is particularly easily peeled off from a substrate. In the optical modulation device 3 according to this embodiment, by causing the thicknesses of the end portion regions 50P, 51P, and 52P of the signal electrode 50, the first ground electrode 51, and the second ground electrode 52 to be 10 μm or more, an effect of preventing the end portion regions 50P, 51P, and 52P of the signal electrode 50, the first ground electrode 51, and the second ground electrode 52 from peeling off from the substrate 31 in this embodiment is relatively effectively exhibited. Moreover, it becomes easy to bond the conductive members to the end portion regions 50P, 51P, and 52P of the signal electrode 50, the first ground electrode 51, and the second ground electrode 52. The thicknesses of the end portion regions 50P, 51P, and 52P of the signal electrode 50, the first ground electrode 51, and the second ground electrode 52 mean the thicknesses of regions of the end portion regions 50P, 51P, and 52P in the Z-axis direction excluding the sectional-view corner portions 50F, 51F, and 52F (see FIG. 4), which will be described later. In addition, the thicknesses of the end portion regions 50P, 51P, and 52P of the signal electrode 50, the first ground electrode 51, and the second ground electrode 52 may be 100 μm or less.

Moreover, in the optical modulation device 3 according to this embodiment, it is preferable that the R-chamfered shapes of the planar-view corner portions 50E1, 50E2, 51E, and 52E of the end portion regions 50P, 51P, and 52P of the signal electrode 50, the first ground electrode 51, and the second ground electrode 52 have radius of curvature R50E1, R50E2, R51E, and R52E of 1 μm or more, and preferably 10 μm or more. Accordingly, stress is particularly less likely to remain between the planar-view corner portions 50E1, 50E2, 51E, and 52E and the member positioned immediately therebelow, and the planar-view corner portions 50E1, 50E2, 51E, and 52E are particularly effectively prevented from peeling off from the substrate 31.

From a geometric viewpoint, the upper limits of the radius of curvature R50E1, R50E2, R51E, and R52E of the R-chamfered shapes of the planar-view corner portions 50E1, 50E2, 51E, and 52E of the end portion regions 50P, 51P, and 52P of the signal electrode 50, the first ground electrode 51, and the second ground electrode 52 may be values that are half the widths of the end portion regions 50P, 51P, and 52P. Specifically, the upper limits of the radius of curvature R50E1, R50E2, R51E, and R52E are, for example, 100 μm or less, and preferably 50 μm or less.

In addition, in the optical modulation device 3 according to this embodiment, since the sectional-view corner portions 50F, 51F, and 52F respectively have the R-chamfered shapes, the sectional-view corner portions 50F, 51F, and 52F have shapes in which the upper portions closest to the outer edge E1 side (+X-axis direction side), which are regions to which physical stimulation (for example, contact by handling means during handling of the optical modulation device 3 to seal the optical modulation device 3 in the package case 9, or contact by a brush during scrub cleaning) is likely to be applied, are cut off. Accordingly, the peeling of the end portion regions 50P, 51P, and 52P of the signal electrode 50, the first ground electrode 51, and the second ground electrode 52 of the optical modulation device 3 from the substrate 31 due to physical stimulation is prevented.

In addition, since the peeling of the end portion regions 50P, 51P, and 52P of the electrodes from the substrate 31 is prevented, the bristles of the brush used for scrub cleaning is prevented from being damaged and cut by the peeled end portion regions 50P, 51P, and 52P of the electrodes, and thus the generation of foreign matter caused by the bristles of the brush is suppressed. Moreover, since the planar-view corner portions 50E1, 50E2, 51E, and 52E have the R-chamfered shapes, compared to a case where the planar-view corner portions 50E1, 50E2, 51E, and 52E do not have the chamfered shapes, a portion from which foreign matter is swept during scrub cleaning is enlarged. Therefore, foreign matter in the side surface regions (in this embodiment, a region between the signal electrode 50 and the first ground electrode 51 and a region between the signal electrode 50 and the second ground electrode 52) of the signal electrode 50, the first ground electrode 51, and the second ground electrode 52 is easily swept out by scrub cleaning, and thus foreign matter is prevented from remaining in the side surface regions of the signal electrode 50, the first ground electrode 51, and the second ground electrode 52 after scrub cleaning.

Furthermore, in the optical modulation device 3 according to this embodiment, it is preferable that the R-chamfered shapes of the sectional-view corner portions 50F, 51F, and 52F of the end portion regions 50P, 51P, and 52P of the signal electrode 50, the first ground electrode 51, and the second ground electrode 52 have radius of curvature R50F, R51F, and R52F of 1 μm or more, and preferably 10 μm or more. Accordingly, the sectional-view corner portions 50F, 51F, and 52F have shapes in which the regions to which physical stimulation is likely to be applied are sufficiently cut off. As a result, the peeling of the end portion regions 50P, 51P, and 52P of the signal electrode 50, the first ground electrode 51, and the second ground electrode 52 of the optical modulation device 3 from the substrate 31 due to physical stimulation is more reliably prevented.

In addition, the upper limits of the radius of curvature R50F, R51F, R52F of the R-chamfered shapes of the sectional-view corner portions 50F, 51F, and 52F of the end portion regions 50P, 51P, and 52P of the signal electrode 50, the first ground electrode 51, and the second ground electrode 52 are, for example, equal to or less than the thicknesses of the end portion regions 50P, 51P, and 52P of the electrodes.

The electrode material of the signal electrode 50, the first ground electrode 51, and the second ground electrode 52 is preferably a low-resistance material for the prevention of signal attenuation. As such an electrode material, gold, silver, or copper is preferable, and gold is most preferable since it is less likely to be altered. In order to prevent the attenuation of a high frequency, it is preferable that the surface of the electrode is smooth to reduce the influence of a skin effect. A thick electrode is formed by plating. In order to cause the surface to be smooth and have a mirrored surface, a gold plating solution which undergoes grain growth to reach a grain size of about several tens of nanometers is widely used. In a case where a gold plating solution which undergoes grain growth to reach a grain size of about several micrometers is used, the corner portion of the electrode end has roundness even when the electrode pattern of a photomask is not chamfered. Accordingly, a peeling prevention effect is obtained to the same level as when chamfering is performed.

Since gold is ductile, when a material piece having a higher hardness than that of gold is rubbed against the upper surfaces of the signal electrode 50, the first ground electrode 51, and the second ground electrode 52, grooves or scratches are inscribed due to cutting or deformation. Accordingly, burrs and projections are likely to be formed in the end portion regions 50P, 51P, and 52P of the electrodes. Since the outer edge portions of the electrodes which become portions where foreign matter, such as cut pieces, is swept out of the substrate 31 are chamfered, the generation of burrs and projections described above can be effectively suppressed. Pressure of the foreign matter such as cut pieces applied by the brush to each of the electrodes during scrub cleaning is on average about 10 g/cm² to 50 g/cm², and a locally high pressure may also be applied due to the uneven structure of the electrode or the uneven density of the bristles of the brush. In addition, since the Vickers hardness of gold is as soft as 20 HV to 30 HV, an indentation having a depth of 2 μm is formed in each of the electrodes. The depth of the grooves or scratches that are actually formed is 0 μm to about 7 μm at the maximum, and is significantly deeper than the depth of the Vickers indentation. Therefore, when the planar-view corner portions 50E1, 50E2, 51E, and 52E and the sectional-view corner portions 50F, 51F, and 52F of the end portion regions 50P, 51P, and 52P of the electrodes are chamfered by 10 μm, the generation of burrs and projections described above can be almost completely prevented.

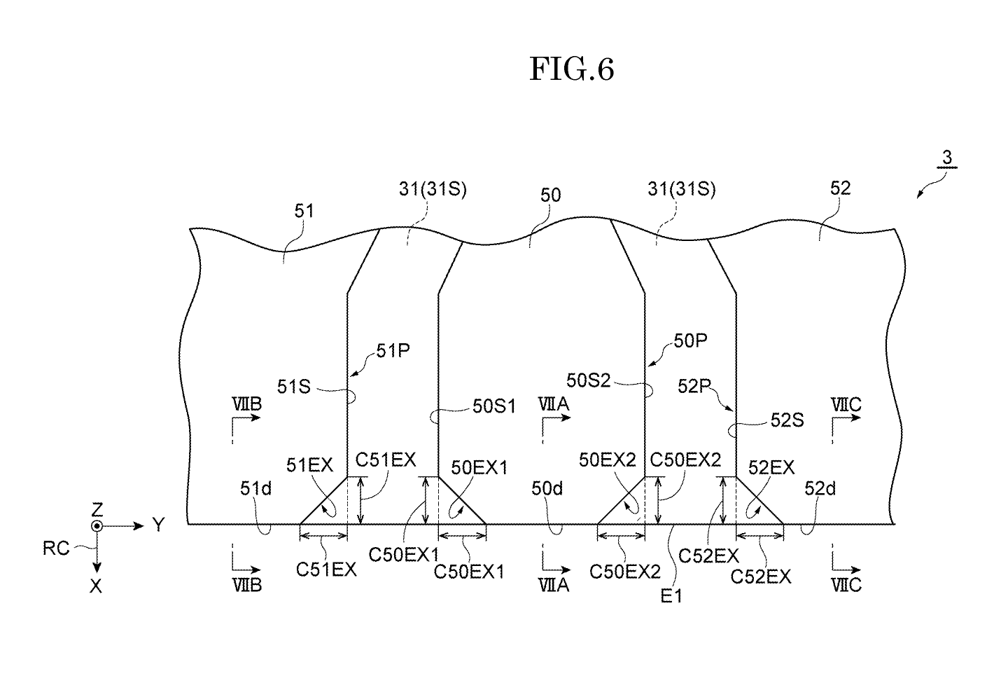

Next, a modification example of this embodiment will be described. FIG. 6 is a view illustrating the planar configuration of the vicinity of a relay section of an optical modulation device according to the modification example, and corresponds to FIG. 3 described above.

In this modification example, the end portion region 50P of the signal electrode 50 includes a planar-view corner portion 50EX1 between the tip end outer edge 50d and the side surface outer edge 5051, and includes a planar-view corner portion 50EX2 between the tip end outer edge 50d and the side surface outer edge 5052. In addition, the planar-view corner portions 50EX1 and 50EX2 have chamfered shapes, and specifically, have C-chamfered shapes having predetermined C-chamfer lengths of C50EX1 and C50EX2, respectively.

Similarly, in this modification example, the end portion region 51P of the first ground electrode 51 includes a planar-view corner portion 51EX between the tip end outer edge 51d and the side surface outer edge 51S. In addition, the planar-view corner portion 51EX has a chamfered shape, and specifically, has a C-chamfered shape having a predetermined C-chamfer length C51EX.

Similarly, in this modification example, the end portion region 52P of the second ground electrode 52 includes a planar-view corner portion 52EX between the tip end outer edge 52d and the side surface outer edge 52S. In addition, the planar-view corner portion 52EX has a chamfered shape, and specifically, has a C-chamfered shape having a predetermined C-chamfer length C52EX.

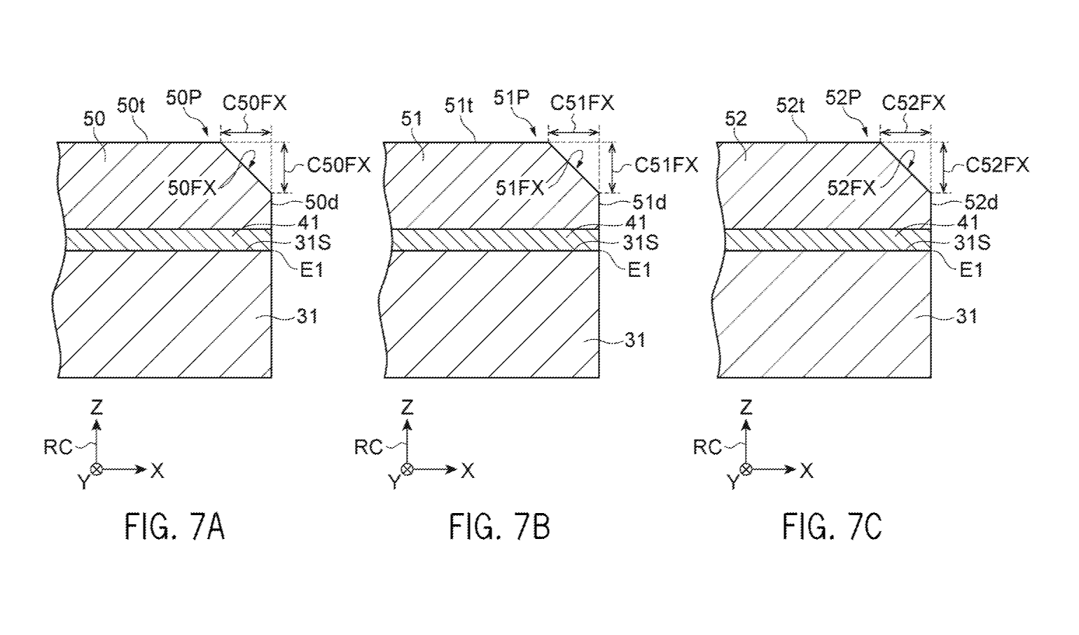

Next, the sectional shape of the optical modulation device 3 according to this modification example will be described. FIG. 7A is a sectional view of the optical modulation device taken along line VIIA-VIIA of FIG. 6, FIG. 7B is a sectional view of the optical modulation device taken along line VIIB-VIIB of FIG. 6, and FIG. 7C is a sectional view of the optical modulation device taken along line VIIC-VIIC of FIG. 6. That is, FIGS. 7A, 7B, and 7C illustrate the sections of the optical modulation device taken along the XZ-plane.

As illustrated in FIG. 7A, the signal electrode 50 includes a sectional-view corner portion 50FX between the tip end outer edge 50d and the upper surface outer edge 50t. In addition, the sectional-view corner portion 50FX has a chamfered shape, and specifically, in this modification example, has a C-chamfered shape having a predetermined C-chamfer length C50FX.

Similarly, as illustrated in FIG. 7B, the first ground electrode 51 includes a sectional-view corner portion 51FX between the tip end outer edge 51d and the upper surface outer edge 51t. In addition, the sectional-view corner portion 51FX has a chamfered shape, and specifically, in this modification example, has a C-chamfered shape having a predetermined C-chamfer length C51FX.

Similarly, as illustrated in FIG. 7C, the second ground electrode 52 includes a sectional-view corner portion 52FX between the tip end outer edge 52d and the upper surface outer edge 52t. In addition, the sectional-view corner portion 52FX has a chamfered shape, and specifically, in this modification example, has a C-chamfered shape having a predetermined C-chamfer length C52FX.

In the optical modulation device 3 according to this modification example as described above, the planar-view corner portions 50EX1, 50EX2, 51EX, and 52EX have the C-chamfered shapes and thus have shapes with larger angles than those in a case where the planar-view corner portions 50EX1, 50EX2, 51EX, and 52EX do not have the C-chamfered shapes. That is, in a case where the planar-view corner portions 50EX1, 50EX2, 51EX, and 52EX do not have C-chamfered shapes, it follows that the planar-view corner portion 50EX1 has a shape with an angle of 90 degrees corresponding to the angle between the extension line of the tip end outer edge 50d and the extension line of the side surface outer edge 50S1, and for the same reason, the planar-view corner portions 50EX2, 51EX, and 52EX also have shapes with an angle of 90 degrees in this modification example.

However, since each of the planar-view corner portions 50EX1, 50EX2, 51EX, and 52EX has the C-chamfered shape, the planar-view corner portions 50EX1, 50EX2, 51EX, and 52EX have curved shapes with a larger obtuse angle. Accordingly, stress is less likely to remain in the planar-view corner portions 50EX1, 50EX2, 51EX, and 52EX, and thus the planar-view corner portions 50EX1, 50EX2, 51EX, and 52EX are prevented from peeling off from the substrate 31.

Moreover, in the optical modulation device 3 according to this modification example, it is preferable that the C-chamfered shapes of the planar-view corner portions 50EX1, 50EX2, 51EX, and 52EX have C-chamfer lengths C50EX1, C50EX2, C51EX, and C52EX of 0.5 μm or more, and preferably 14 μm or more. Accordingly, stress is particularly less likely to remain in the planar-view corner portions 50EX1, 50EX2, 51EX, and 52EX, and thus the planar-view corner portions 50EX1, 50EX2, 51EX, and 52EX are particularly effectively prevented from peeling off from the substrate 31.

Furthermore, in the optical modulation device 3 according to this modification example, since each of the sectional-view corner portions 50FX, 51FX, and 52FX has the C-chamfered shape, for the same reason as in the case of the basic embodiment described above, the peeling of the end portion regions 50P, 51P, and 52P of the signal electrode 50, the first ground electrode 51, and the second ground electrode 52 of the optical modulation device 3 from the substrate 31 due to physical stimulation is prevented.

Furthermore, in the optical modulation device 3 according to this modification example, it is preferable that the C-chamfered shapes of the sectional-view corner portions 50FX, 51FX, and 52FX of the end portion regions 50P, 51P, and 52P of the signal electrode 50, the first ground electrode 51, and the second ground electrode 52 have C-chamfer lengths C50FX, C51FX, and C52FX of 1.4 μm or more, and preferably 14 μm or more. Accordingly, the sectional-view corner portions 50FX, 51FX, and 52FX have shapes in which the regions to which physical stimulation is likely to be applied are sufficiently cut off. As a result, the peeling of the end portion regions 50P, 51P, and 52P of the signal electrode 50, the first ground electrode 51, and the second ground electrode 52 of the optical modulation device 3 from the substrate 31 due to physical stimulation is more reliably prevented.

In addition, the upper limits of the C-chamfer lengths C50FX, C51FX, and C52FX of the C-chamfered shapes of the sectional-view corner portions 50FX, 51FX, and 52FX of the end portion regions 50P, 51P, and 52P of the signal electrode 50, the first ground electrode 51, and the second ground electrode 52 are, for example, equal to or less than the thicknesses of the end portion regions 50P, 51P, and 52P of the electrodes.

The present invention is not limited to the above-described embodiments, and various modifications can be made. For example, in the above-described embodiments, the end portion regions 50P, 51P, and 52P of the signal electrode 50, the first ground electrode 51, and the second ground electrode 52 have both of the chamfered planar-view corner portions 50E1, 50E2, 51E, 52E, 50EX1, 50EX2, 51EX, and 52FX (see FIGS. 3 and 6) and the chamfered sectional-view corner portions 50F, 51F, 52F, 50FX, 51FX, and 52FX (see FIGS. 4 and 7), but may also have only one thereof.

In addition, in the above-described embodiments, the planar-view corner portions 50E1, 51E, and 52E of the signal electrode 50, the first ground electrode 51, and the second ground electrode 52 have the R-chamfered shapes or the C-chamfered shapes, but may also have another chamfered shape.

In addition, in the above-described embodiments, the sectional-view corner portions 50F, 51F, and 52F of the signal electrode 50, the first ground electrode 51, and the second ground electrode 52 have the R-chamfered shapes or the C-chamfered shapes, but may also have another chamfered shape.

Next, Examples will be described. In Examples 1 to 35, eight signal electrodes having a width of 30 μm and a height of 20 μm were provided. Optical modulation devices were prepared. In Examples 1 to 7, an electrode having a planar-view corner portion having an R-chamfered shape in an end portion region was formed by the design-time chamfering method. The radius of curvature of the R-chamfered shape was 0.5 μm, 1 μm, 3 μm, 5 μm, 7 μm, 10 μm, and 17 μm in order of Examples 1 to 7. In Examples 8 to 14, an electrode having a planar-view corner portion having an R-chamfered shape in an end portion region was formed by the post-electrode formation chamfering method. The radius of curvature of the R-chamfered shape was 0.5 μm, 1 μm, 3 μm, 5 μm, 7 μm, 10 μm, and 17 μm in order of Examples 8 to 14.

In Examples 15 to 21, after an electrode having a typical shape was formed, an electrode having a sectional-view corner portion having a C-chamfered shape in an end portion region was formed by mechanically and physically etching the sectional-view corner portion. The C-chamfer length of the C-chamfered shape was 0.5 μm, 1 μm, 3 μm, 5 μm, 7 μm, 10 μm, and 17 μm in order of Examples 15 to 21. In Examples 22 to 28, after an electrode having a sectional-view corner portion having a C-chamfered shape in an end portion region was formed in the same manner as in Examples 15 to 21, and a planar-view corner portion of the end portion region of the electrode was processed to have an R-chamfered shape by the post-electrode formation chamfering method. The radius of curvature of the R-chamfered shape was the same as the C-chamfer length of the C-chamfered shape in Examples, that is, was 0.5 μm, 1 μm, 3 μm, 5 μm, 7 μm, 10 μm, and 17 μm in order of Examples 22 to 28.

In Examples 29 to 35, an electrode having a planar-view corner portion having an R-chamfered shape in an end portion region was formed by the design-time chamfering method. The radius of curvature of the R-chamfered shape was 0.5 μm, 1 μm, 3 μm, 5 μm, 7 μm, 10 μm, and 17 μm in order of Examples 29 to 35. Thereafter, a sectional-view corner portion of the end portion region of the electrode was processed to have a C-chamfered shape through mechanical and physical etching. The C-chamfer length of the C-chamfered shape was 1 μm in all of Examples 29 to 35.

In each of Examples 1 to 35 described above, raising and lowering by a handling tool were repeated 40 times. Thereafter, in each of Examples, the number of electrodes where peeling had occurred was counted.

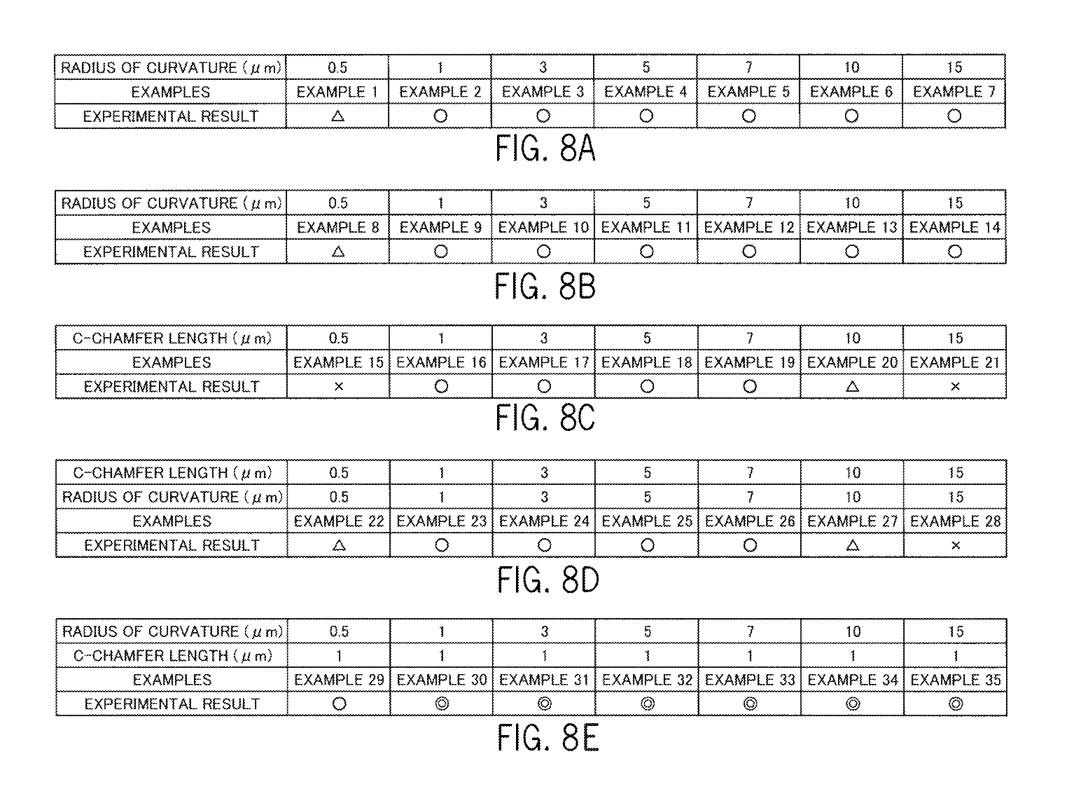

FIGS. 8A, 8B, 8C, 8D, and 8E are tables showing the experimental results corresponding to Examples 1 to 7, Examples 8 to 14, Examples 15 to 21, Examples 22 to 28, and Examples 29 to 35. In FIGS. 8A, 8B, 8C, 8D, and 8E, “ ” represents that the number of electrodes where peeling had occurred after the experiment was 1 or less, “ ” represents that the number of the corresponding electrodes was 2 or more and 3 or less, “ ” represents that the number of the electrodes was 4 or more and 5 or less, and “X” represents that the number of the corresponding electrodes was 6 or more.

What is claimed is:

1. An electrode-placed substrate comprising:
a substrate having a principal surface; and
a coplanar electrode or a coplanar strip electrode which has a pair of a signal electrode and a ground electrode provided on the principal surface of the substrate,
wherein the signal electrode or the ground electrode has an end portion region on an outer edge side of the principal surface of the substrate in a plan view, the end portion region extending in a first direction intersecting the outer edge, and
in the plan view, a planar-view corner portion provided between a tip end outer edge which defines a tip end shape of the end portion region in the first direction and a side surface outer edge which defines a side surface shape of the end portion region has a chamfered shape, or in a sectional view across a section which is parallel to the first direction and is perpendicular to the principal surface of the substrate, a sectional-view corner portion provided between the tip end outer edge which defines the tip end shape of the end portion region in the first direction and an upper surface outer edge which defines an upper surface shape of the end portion region has a chamfered shape.

2. The electrode-placed substrate according to claim 1,
wherein a thickness of the end portion region of the signal electrode or the ground electrode is 30 μm or more and 100 μm or less.

3. The electrode-placed substrate according to claim 1,
wherein the planar-view corner portion of the end portion region of the signal electrode or the ground electrode has an R-chamfered shape in the plan view.

4. The electrode-placed substrate according to claim 3,
wherein the R-chamfered shape of the planar-view corner portion of the end portion region of the signal electrode or the ground electrode has a radius of curvature of 1 μm or more.

5. The electrode-placed substrate according to claim 1,
wherein the planar-view corner portion of the end portion region of the signal electrode or the ground electrode has a C-chamfered shape in the plan view.

6. The electrode-placed substrate according to claim 5,
wherein the C-chamfered shape of the planar-view corner portion of the end portion region of the signal electrode or the ground electrode has a chamfer length of 0.5 μm or more.
